(19) United States
(12) Patent Application Publication
(10) Pub. No.: US 2020/0273830 A1
(43) Pub. Date: Aug. 27, 2020

(54) SEMICONDUCTOR DEVICE AND METHOD FOR MANUFACTURING THE SAME

(71) Applicant: Nepes Co., Ltd., Chungcheongbuk-do (KR)

(72) Inventors: Yong Tae Kwon, Chungcheongbuk-do (KR); Jun Kyu LEE, Chungcheongbuk-do (KR); Kyeong Rok SHIN, Gwangju (KR)

(73) Assignee: Nepes Co., Ltd., Chungcheongbuk-do (KR)

(21) Appl. No.: 16/792,518

(22) Filed: Feb. 17, 2020

(30) Foreign Application Priority Data
Feb. 27, 2019 (KR) 10-2019-0023289
Jun. 21, 2019 (KR) 10-2019-0074125
Nov. 25, 2019 (KR) 10-2019-0152232

(51) Int. Cl. H01L 23/00; H01L 23/522; H01L 21/768

(52) U.S. Cl. CPC H01L 24/13; H01L 23/5226; H01L 24/05; H01L 21/76804; H01L 2224/0401; H01L 21/76877; H01L 24/03; H01L 2224/02331; H01L 21/76807

(57) ABSTRACT

A semiconductor package according to an embodiment includes a semiconductor chip having a first surface in which a chip pad is formed, a first insulating layer arranged on the first surface of the semiconductor chip and including a first filler, a first conductive via electrically connected to the chip pad and formed to penetrate the first insulating layer, a redistribution pattern electrically connected to the first conductive via and buried in the first insulating layer, a second insulating layer contacting the redistribution pattern on the first insulating layer and including a second filler, a second conductive via electrically connected to the redistribution pattern and formed to penetrate the second insulating layer, an under bump material (UBM) electrically connected to the second conductive via and buried in the second insulating layer, and an external connection terminal electrically connected to the UBM.

### CROSS-REFERENCE TO RELATED APPLICATIONS

This application claims the benefit of Korean Patent Application Nos. 10-2019-0023289, 10-2019-0074125 and 10-2019-0152232, respectively filed on Feb. 27, 2019, Jun. 21, 2019, and Nov. 25, 2019, in the Korean Intellectual Property Office, the disclosures of which are incorporated herein in their entireties by reference.

### BACKGROUND

### 1. Field

One or more embodiments relate to a semiconductor package and a semiconductor package manufacturing method, and more particularly, to a semiconductor package which enables reduction of a manufacturing cost through a simplified process and a method of manufacturing the semiconductor package.

### 2. Description of Related Art

With an increase in the storage capacity of semiconductor chips, semiconductor packages including semiconductor chips are required to be thin and light. A plurality of manufacturing processes and inspection processes for determining whether the manufacturing processes operate normally are executed in order to manufacture small and high-capacity semiconductor packages. Recently, semiconductor package manufacturers have attempted to reduce the manufacturing cost of semiconductor packages by simplifying the manufacturing processes and the inspection processes.

### SUMMARY

An aspect of the present disclosure is to provide a semiconductor package which is less vulnerable to an external impact and has excellent durability.

Another aspect of the present disclosure is to provide a method of manufacturing a semiconductor package, which enables reduction of a manufacturing cost through a simplified manufacturing process.

Another aspect of the present disclosure is to provide a method of manufacturing a semiconductor package, which enables production of a thin and light semiconductor package.

Additional aspects will be set forth in part in the description which follows and, in part, will be apparent from the description, or may be learned by practice of the presented embodiments of the disclosure.

According to one or more embodiments, a semiconductor package includes: a semiconductor chip having a first surface in which a chip pad is formed; a first insulating layer arranged on the first surface of the semiconductor chip and including a first filler; a first conductive via electrically connected to the chip pad and formed to penetrate the first insulating layer; and a redistribution pattern electrically connected to the first conductive via and buried in the first insulating layer.

In an example embodiment, the semiconductor package may include: a second insulating layer contacting the redistribution pattern on the first insulating layer and including a second filler; a second conductive via electrically connected to the redistribution pattern and formed to penetrate the second insulating layer; a UBM electrically connected to the second conductive via and buried in the second insulating layer; and an external connection terminal electrically connected to the UBM.

In an example embodiment, the first filler and the second filler may include at least one of silica and alumina, and may have a size of from about 0.1 micrometers to about 10 micrometers.

In an example embodiment, a mixing proportion of the first filler of the first insulating layer may be different from a mixing proportion of the second filler of the second insulating layer.

In an example embodiment, the mixing proportion of the first filler of the first insulating layer may be lower than the mixing proportion of the second filler of the second insulating layer.

In an example embodiment, the first filler may have a high density in a region of the first insulating layer adjacent to the first conductive via and the redistribution pattern.

In an example embodiment, the first insulating layer may include: a first upper adhesive layer on the semiconductor chip; and a first filler layer arranged on the first upper adhesive layer and including the first filler, and the second insulating layer may include: a second upper adhesive layer on the first filler layer; and a second filler layer arranged on the second upper adhesive layer and including the second filler.

In an example embodiment, the first insulating layer may further include a first lower adhesive layer interposed between the first filler layer and the second upper adhesive layer, and the second insulating layer further include a second lower adhesive layer on the second filler layer.

In an example embodiment, the redistribution pattern may be tapered so that a cross-sectional area thereof decreases in a direction towards the semiconductor chip.

In an example embodiment, a sum of thicknesses of the first conductive via and the redistribution pattern may be the same as a thickness of the first insulating layer.

In an example embodiment, a lower surface of the redistribution pattern may be closer to the semiconductor chip in a vertical direction than an upper surface of the first insulating layer.

According to one or more embodiments, a semiconductor package includes: a semiconductor chip having a first surface in which a chip pad is formed; a first insulating layer on the first surface of the semiconductor chip; a first conductive via electrically connected to the chip pad and formed to penetrate the first insulating layer; a redistribution pattern electrically connected to the first conductive via and buried in the first insulating layer; a second insulating layer contacting the redistribution pattern on the first insulating layer; a second conductive via electrically connected to the redistribution pattern and formed to penetrate the second insulating layer; a UBM electrically connected to the second conductive via and buried in the second insulating layer; and an external connection terminal electrically connected to the UBM, wherein the redistribution pattern is tapered so that a cross-sectional area thereof decreases in a direction towards the semiconductor chip.

In an example embodiment, a cross section of the redistribution pattern may have a shape of at least one of a triangle, a trapezoid, a stair, and a semicircle.

In an example embodiment, the first insulating layer may include a first filler, and the second insulating layer may include a second filler.

According to one or more embodiments, a method of manufacturing a semiconductor package includes: forming a first insulating layer including a first filler on a first surface of a semiconductor chip in which a chip pad is formed; forming a first via hole and a redistribution pattern hole by stamping the first insulating layer; forming a first conductive via and a redistribution pattern by filling the first via hole and the redistribution pattern hole with a first conductive material; forming a second insulating layer including a second filler on the first insulating layer; forming a second via hole and a UBM pattern hole by stamping the second insulating layer; and forming a second conductive via and a UBM by filling the second via hole and the UBM pattern hole with a second conductive material.

In an example embodiment, the forming of the first insulating layer may include: forming a first upper adhesive layer on the first surface of the semiconductor chip; forming a first filler layer including the first filler on the first upper adhesive layer; and forming a first lower adhesive layer on the first filler layer.

In an example embodiment, the forming of the first insulating layer may include attaching, to the first surface of the semiconductor chip, the first insulating layer of a film type in which a first upper adhesive layer, a first filler layer including the first filler, and a first lower adhesive layer are sequentially stacked.

In an example embodiment, the forming of the second insulating layer may include: forming a second upper adhesive layer on the first insulating layer; forming a second filler layer including the second filler on the second upper adhesive layer; and forming a second lower adhesive layer on the second filler layer.

In an example embodiment, the forming of the second insulating layer may include attaching, to the first insulating layer, the second insulating layer of a film type in which a second upper adhesive layer, a second filler layer including the second filler, and a second lower adhesive layer are sequentially stacked.

In an example embodiment, the forming of the redistribution pattern hole may include stamping the first insulating layer to form the redistribution pattern hole having a tapered shape, a cross-sectional area of which decreases in a direction towards the first surface of the semiconductor chip.

In an example embodiment, the forming of the redistribution pattern hole may include forming the redistribution pattern hole in the shape of at least one of a triangle, a trapezoid, a stair, and a semicircle.

The semiconductor package according to an embodiment may have excellent durability, and thus may be less vulnerable to an external impact. The method of manufacturing a semiconductor package according to an embodiment may include a stamping process so as to make it possible to manufacture a semiconductor package at a low manufacturing cost. The method of manufacturing a semiconductor package according to an embodiment may include a stamping process so as to make it possible to manufacture a thin and light semiconductor package.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional view of a semiconductor package according to an embodiment.

FIG. 2 is a cross-sectional view of semiconductor package according to an embodiment.

FIG. 3 is a cross-sectional view of a semiconductor package according to an embodiment.

FIGS. 4 to 7 are cross-sectional views of a redistribution pattern according to an embodiment.

FIGS. 8 to 24 are diagrams illustrating a method of manufacturing a semiconductor package according to an embodiment.

### DETAILED DESCRIPTION

Hereinafter, embodiments of the present disclosure will be described in detail with reference to the accompanying drawings. However, the embodiments of the present disclosure may be modified into other various forms, and the scope of the concept of the present disclosure should not be construed as being limited to the embodiments described below. The embodiments of the present disclosure are provided so that this disclosure will be thorough and complete, and will fully convey the concept of the present disclosure to those skilled in the art. The same reference numerals refer to the same elements throughout. Various elements and regions are schematically illustrated in the drawings. Therefore, the concept of the present disclosure is not limited to the relative sizes or spaces illustrated in the accompanying drawings.

The terms “first”, “second”, and the like may be used for describing various elements, but the elements are not limited by the terms. The above terms are used only for distinguishing one element from other elements. For example, a first element could be termed a second element and vice versa without departing from the scope of the right of the concept of the present disclosure.

The terminology used herein is not for delimiting the concept of the present disclosure but for describing specific embodiments. The terms of a singular form may include plural forms unless otherwise specified. It will be further understood that the terms “comprise”, “comprising”, “include”, “including”, “have”, “having”, and the like, when used herein, specify the presence of stated features, numbers, steps, operations, elements, components, or combinations thereof, but do not preclude the presence or addition of one or more other features, numbers, operations, elements, components, or combinations thereof.

The terms used herein, including technical and scientific terms, have the same meanings as understood by those skilled in the art unless otherwise defined. Furthermore, it would be understood that terms in common usage such as those defined in dictionaries should be interpreted to contextually match the meanings in the relevant art, and should not be interpreted in an overly formal sense unless otherwise defined explicitly.

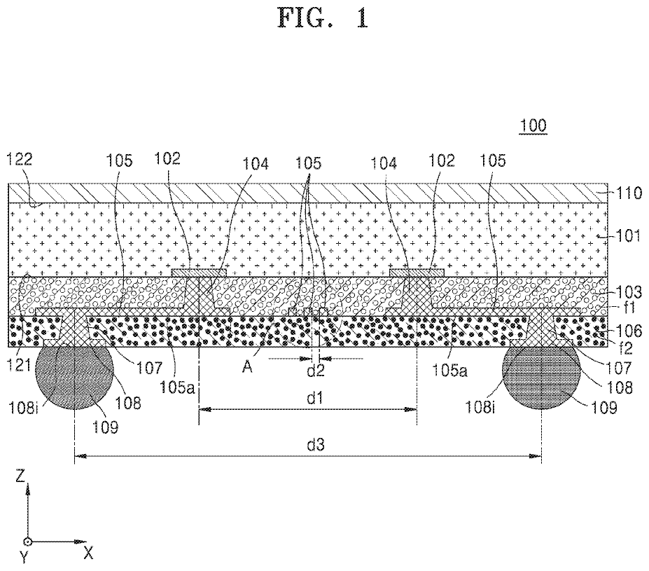

FIG. 1 is a cross-sectional view of a semiconductor package 100 according to an embodiment. The semiconductor package 100 may be a wafer level package (WLP). For example, the semiconductor package 100 may be a fan-out wafer level package (FOWLP). However, the semiconductor package 100 is not limited thereto, and may be a panel level package (PLP).

Referring to FIG. 1, the semiconductor package 100 according to an embodiment may include a semiconductor chip 101, a chip pad 102, a first insulating layer 103, a first conductive via 104, a redistribution pattern 105, a second insulating layer 106, a second conductive via 107, an under bump material (UBM) 108, an external connection terminal 109, and a protective layer 110.

The semiconductor chip 101 of the semiconductor package 100 according to an embodiment may include a plurality of various types of individual devices. For example, the individual devices may include various microelectronic devices, for example, a metal-oxide semiconductor field effect transistor (MOSFET) such as a complementary metal-oxide semiconductor (CMOS) transistor, a system large scale integration (LSI), an image sensor such as a CMOS imaging sensor (CIS), a micro-electro-mechanical system (MEMS), an active device, a passive device, etc.

In an embodiment, the semiconductor chip 101 may be a semiconductor memory chip. The semiconductor memory chip may be, for example, a volatile semiconductor memory chip such as dynamic random access memory (DRAM) or static random access memory (SRAM) or a non-volatile semiconductor memory chip such as phase-change random access memory (PRAM), magneto-resistive random access memory (MRAM), ferroelectric random access memory (FeRAM), or resistive random access memory (RRAM).

The semiconductor chip 101 may be a logic chip. For example, the semiconductor chip 101 may be a central processing unit (CPU), a microprocessor unit (MPU), a graphics processor unit (GPU), or an application processor (AP).

Although the semiconductor package 100 is illustrated as including a single semiconductor chip 101 in FIG. 1, the semiconductor package 100 may include a plurality of semiconductor chips 101. The plurality of semiconductor chips 101 included in the semiconductor package 100 may be homogeneous semiconductor chips or may be heterogeneous semiconductor chips. The semiconductor package 100 may be a system in package (SIP) in which different types of semiconductor chips are electrically connected to operate as one system.

In an embodiment, a length of the semiconductor chip 101 in an X direction may be from about 2 millimeters to about 10 millimeters. Furthermore, a length of the semiconductor chip 101 in a Y direction may be from about 2 millimeters to about 10 millimeters. In more detail, the lengths of the semiconductor chip 101 in the X direction and in the Y direction may be from about 4 millimeters to about 7 millimeters. However, the lengths of the semiconductor chip 101 in the X direction and in the Y direction are not limited thereto, and may have other various values.

Furthermore, a length of the semiconductor chip 101 in a Z direction (hereinafter referred to as a thickness of the semiconductor chip 101) may be from about 100 micrometers to about 400 micrometers. In more detail, the thickness of the semiconductor chip 101 may be from about 150 micrometers to about 300 micrometers. However, the thickness of the semiconductor chip 101 is not limited thereto, and may have other various values.

The semiconductor chip 101 may have a first surface 121 and a second surface 122 facing the first surface 121. The chip pad 102 may be formed in the first surface 121 of the semiconductor chip 101. The chip pad 102 may be electrically connected to the various types of individual devices formed in the semiconductor chip 101. The chip pad 102 may have a thickness of from about 0.5 micrometers to about 1.5 micrometers. However, the thickness of the chip pad 102 is not limited thereto, and may have various other values. Furthermore, although not illustrated in FIG. 1, a protective layer (not shown) may be formed on the first surface 121 of the semiconductor chip 101. The protective layer may expose the chip pad 102.

The first insulating layer 103 of the semiconductor package 100 according to an embodiment may be arranged on the first surface 121 of the semiconductor chip 101. In more detail, the first insulating layer 103 may be arranged between the first surface 121 of the semiconductor chip 101 and the second insulating layer 106 to be described later. The first insulating layer 103 may have a thickness of from about 10 micrometers to about 100 micrometers between the first surface 121 of the semiconductor chip 101 and the second insulating layer 106. In more detail, the first insulating layer 103 may have a thickness of from about 20 micrometers to about 50 micrometers between the first surface 121 of the semiconductor chip 101 and the second insulating layer 106. However, the first insulating layer 103 is not limited thereto, and may have a thickness of about 100 micrometers or more.

The first insulating layer 103 may include a non-conductive material. For example, the first insulating layer 103 may include polyimide or epoxy. However, the first insulating layer 103 is not limited thereto, and may include a silicon oxide film, a silicon nitride film, an insulative polymer, or a combination thereof.

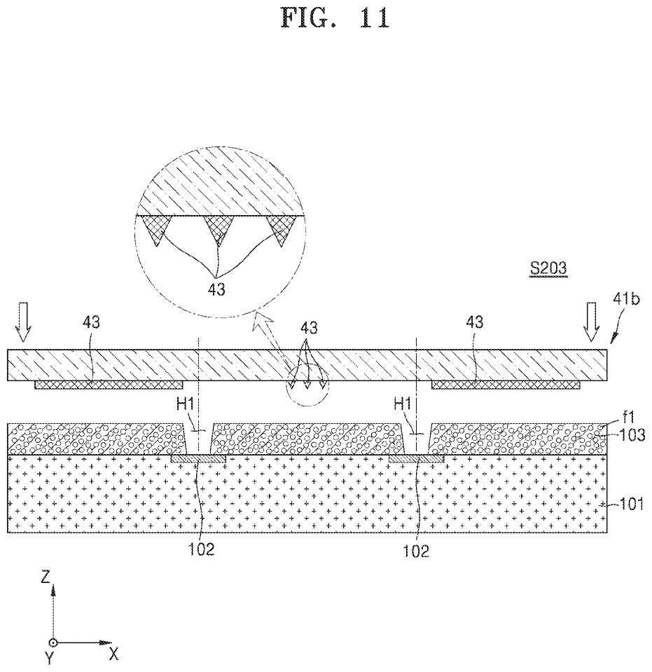

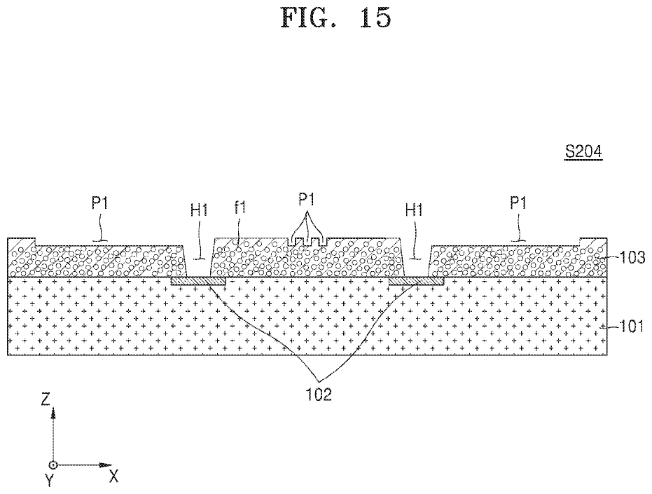

A first via hole H1 (FIG. 11) and a redistribution pattern hole P1 (FIG. 15) may be formed in the first insulating layer 103 through a stamping process to be described later. Since the first via hole H1 and the redistribution pattern hole P1 may be formed through the stamping process rather than a photolithography process, the first insulating layer 103 may include not only a photosensitive material but also a non-photosensitive material.

As described above, the first via hole H1 may be formed in the first insulating layer 103 through the stamping process. In more detail, the first via hole H1 may be formed to penetrate the first insulating layer 103 at a portion in which the chip pad 102 is formed. Furthermore, the first via hole H1 may expose the chip pad 102.

The first via hole H1 of the first insulating layer 103 may have a tapered shape. In more detail, the first via hole H1 may be tapered so that a cross-sectional area thereof increases in a direction away from the chip pad 102.

A diameter of the first via hole H1 may be from about 5 micrometers to about 20 micrometers. For example, when the first via hole H1 has a tapered shape, the first via hole H1 may have a diameter of about 5 micrometers in a region adjacent to the chip pad 102 and may have a diameter of about 15 micrometers in a region adjacent to the redistribution pattern 105.

When the first via hole H1 has a cylindrical structure in which the cross-sectional area thereof is constant, unlike the illustration of FIG. 1, the first via hole H1 may have a diameter of about 10 micrometers in a region adjacent to the chip pad 102 and in a region adjacent to the redistribution pattern 105. However, the diameter of the first via hole H1 is not limited thereto, and may have various values according to various shapes of the first via hole H1.

The first insulating layer 103 may have a plurality of first via holes H1. A separation distance d1 between the first via holes H1 in the X direction may be from about 30 micrometers to about 100 micrometers. However, the separation distance d1 between the first via holes H1 is not limited thereto, and may have various other values.

In an embodiment, the first insulating layer 103 may include a first filler f1. The first filler f1 may include at least one of silica and alumina. Furthermore, the first filler f1 may have a size of from about 0.1 micrometers to about 10 micrometers or less. For example, when the first filler f1 has a spherical shape, a diameter of the first filler f1 may be from about 0.1 micrometers to about 10 micrometers.

Since the first insulating layer 103 may include the first filler f1, the first insulating layer 103 may be easily formed on the first surface 121 of the semiconductor 101. Since the first insulating layer 103 includes the first filler f1, the fluidity of the first insulating layer 103 may be adjusted. In more detail, the fluidity of the first insulating layer 103 may be controlled by controlling a concentration of the first filler f1 in the first insulating layer 103.

In an embodiment, since the first insulating layer 103 includes the first filler f1, the fluidity of the first insulating layer 103 may be reduced. Accordingly, the first insulating layer 103 having a predetermined thickness or more may be formed on the first surface 121 of the semiconductor chip 101. For example, since the first insulating layer 103 may include the first filler f1, the first insulating layer 103 may be formed to a thickness of at least about 10 micrometers on the first surface 121 of the semiconductor chip 101. In an example embodiment, the first insulating layer 103 may be formed to a thickness of from about 10 micrometers to about 100 micrometers.

Furthermore, since the first insulating layer 103 may include the first filler f1, forming the first via hole H1 and the redistribution pattern hole P1 by stamping the first insulating layer 103 may be easily performed. Since the first insulating layer 103 includes the first filler f1, the fluidity of the first insulating layer 103 may be reduced. Accordingly, when detaching a stamp from the first insulating layer 103 after stamping the first insulating layer 103, an upper surface of the first insulating layer 103 may be maintained as a planar surface.

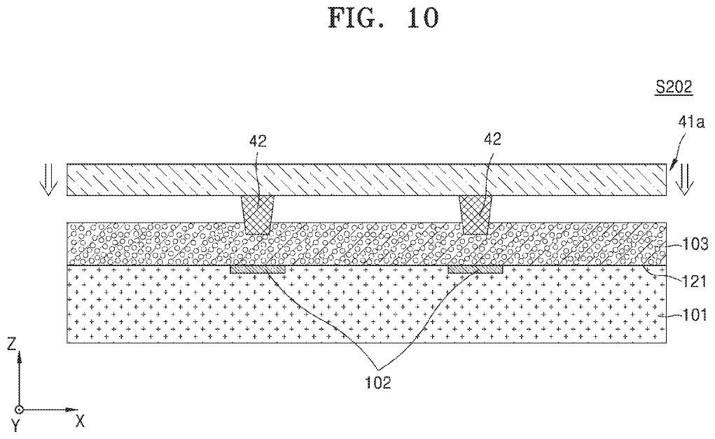

Furthermore, when detaching a stamp from the first insulating layer 103, shapes of the first via hole H1 and the redistribution pattern hole P1 formed in the first insulating layer 103 may substantially conform to shapes of a first via hole protrusion 42 (FIG. 10) of a first stamp 41a (FIG. 10) and a redistribution protrusion 43 (FIG. 11) of a second stamp 41b (FIG. 11). In other words, since the first insulating layer 103 includes the first filler f1 and thus may be reduced in fluidity, the first via hole H1 and the redistribution pattern hole P1 may have smoother shapes than when the first insulating layer 103 does not include the first filler f1. Accordingly, the first conductive via 104 and the redistribution pattern 105 may also have a smooth shape.

Since the first insulating layer 103 may include the first filler f1, the reliability of the semiconductor package 100 may be improved. In more detail, since the first insulating layer 103 includes the first filler f1, a difference of coefficient of thermal expansion (CTE) between the first insulating layer 103 and the first conductive via 104 may be reduced. Accordingly, a possibility of thermal damage to the semiconductor package 100 may be reduced.

Furthermore, since the first insulating layer 103 may include the first filler f1, mechanical stress between the first insulating layer 103 and the first conductive via 104 may be reduced. Accordingly, a possibility of damage to the semiconductor package 100 due to an external impact may be reduced. That is, the durability of the semiconductor package 100 may be improved.

The first conductive via 104 of the semiconductor package 100 according to an embodiment may be a conductive material filling the first via hole H1. The conductive material may be a metal material having excellent conductivity such as copper, gold, silver, or the like.

The first conductive via 104 may contact the chip pad 102 and may be electrically connected to the chip pad 102. Accordingly, the first conductive via 104 may be electrically connected to the various types of individual devices on the semiconductor chip 101. Furthermore, the first conductive via 104 may be electrically connected to the redistribution pattern 105.

The redistribution pattern 105 of the semiconductor package 100 according to an embodiment may include a plurality of redistribution lines for electrically connecting the first conductive via 104 to the second conductive via 107. As illustrated in FIG. 1, the redistribution pattern 105 may be between the first conductive via 104 and the second conductive via 107, and may electrically connect the first conductive via 104 to the second conductive via 107.

As illustrated in FIG. 1, the redistribution pattern 105 may be buried in the first insulating layer 103. In more detail, a first surface 105a of the redistribution pattern 105 may be substantially flush with one surface of the first insulating layer 103. The first insulating layer 103 may expose the first surface 105a of the redistribution pattern 105. That is, a surface of the redistribution pattern 105, which faces the first surface 105a, and side surfaces of the redistribution pattern 105 may be surrounded by the first insulating layer 103.

A surface formed due to a contact between the redistribution pattern 105 and the second insulating layer 106 may be substantially flush with a surface formed due to a contact between the first insulating layer 103 and the second insulating layer 106. Since the redistribution pattern 105 may be buried in the first insulating layer 103, the redistribution pattern 105 may be securely positioned in the first insulating layer 103. Furthermore, since the redistribution pattern 105 may be buried in the first insulating layer 103, a thickness of the semiconductor package 100 may reduce.

Unlike the illustration of FIG. 1, the first surface 105a of the redistribution pattern 105 may be closer to the semiconductor chip 101 than one surface of the first insulating layer 103. In other words, a surface formed due to a contact between the first surface 105a of the redistribution pattern 105 and the second insulating layer 106 may be closer to the semiconductor chip 101 than a surface formed due to a contact between the first insulating layer 103 and the second insulating layer 106. Therefore, a height difference may occur between the surface formed due to a contact between the first surface 105a of the redistribution pattern 105 and the second insulating layer 106 and the surface formed due to a contact between the first insulating layer 103 and the second insulating layer 106.

Furthermore, a second surface of the redistribution pattern 105, which faces the first surface 105a, may be closer to the semiconductor chip 101 than the surface formed due to a contact between the first insulating layer 103 and the second insulating layer 106. For example, the second surface of the redistribution pattern 105 may be from about 0.1 micrometers to about 3 micrometers closer to the semiconductor chip 101 than the surface formed due to a contact between the first insulating layer 103 and the second insulating layer 106.

A lower surface of the redistribution pattern 105 may be closer to the semiconductor chip 101 in a vertical direction than the upper surface of the first insulating layer 103. In more detail, the second surface of the redistribution pattern 105, which faces the first surface 105a, may be closer to the semiconductor chip 101 than the surface formed due to a contact between the first insulating layer 103 and the second insulating layer 106.

The redistribution pattern 105 may include a plurality of redistribution lines. A separation distance d2 between the redistribution lines may be from about 0.5 micrometers to about 3 micrometers. In more detail, the separation distance d2 between the redistribution lines may be from about 0.5 micrometers to about 1.5 micrometers. However, the separation distance d2 between the redistribution lines is not limited thereto, and may have various other values.

Furthermore, a width of the redistribution lines may be from about 0.5 micrometers to about 1.5 micrometers. However, the width of the redistribution lines is not limited thereto, and may have other various values. A thickness of the redistribution lines may be from about 1 micrometer to about 5 micrometers. However, the thickness of the redistribution lines is not limited thereto, and may have other various values. Due to processes of a semiconductor package manufacturing method to be described later, the separation distance d2, width, and thickness of the redistribution pattern 105 may have relatively small values. Therefore, the redistribution lines of the redistribution pattern 105 may be arranged accurately and minutely in the first insulating layer 103.

A material of the redistribution pattern 105 may include a metal material having excellent conductivity such as copper, gold, silver, or the like. Furthermore, the material of the redistribution pattern 105 may be substantially the same as the material of the first conductive via 104. For example, when the material of the first conductive via 104 is copper, the material of the redistribution pattern 105 may include copper.

The second insulating layer 106 of the semiconductor package 100 according to an embodiment may be arranged on the first insulating layer 103. In more detail, the second insulating layer 106 may be arranged on the first insulating layer 103 in contact with the redistribution pattern 105. Furthermore, the second insulating layer 106 may have a thickness of from about 10 micrometers to about 100 micrometers on the first insulating layer 103. In more detail, the second insulating layer 106 may have a thickness of from about 20 micrometers to about 50 micrometers on the first insulating layer 103. However, the second insulating layer 106 is not limited thereto, and may have a thickness of about 100 micrometers or more.

The material of the second insulating layer 106 may be different from that of the first insulating layer 103. Therefore, a boundary surface may be formed between the first insulating layer 103 and the second insulating layer 106. The boundary surface may be substantially flush with the first surface 105a of the redistribution pattern 105 described above. However, the materials of the first insulating layer 103 and the second insulating layer 106 are not limited thereto, and may be the same. In this case, the boundary surface may be not be formed between the first insulating layer 103 and the second insulating layer 106.

The second insulating layer 106 may include a non-conductive material. For example, the second insulating layer 106 may include a photosensitive material such as polyimide or epoxy. However, the second insulating layer 106 is not limited thereto, and may include a silicon oxide film, a silicon nitride film, an insulative polymer, or a combination thereof.

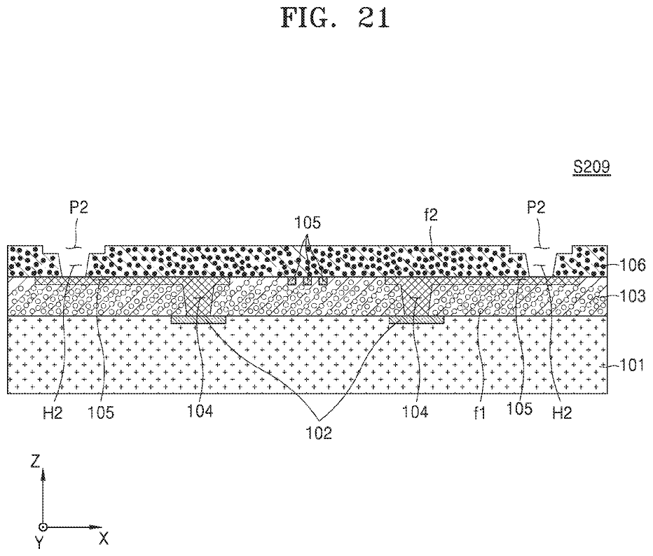

The second insulating layer 106 may have a second via hole H2 (FIG. 21) and a UBM pattern hole P2 (FIG. 21) through a stamping process rather than a photolithography process. Therefore, the second insulating layer 106 may include not only a photosensitive material but also a non-photosensitive material.

The second via hole H2 may be formed to penetrate the second insulating layer 106 at a portion in which the redistribution pattern 105 is formed. The second via hole H2, which is formed to penetrate the second insulating layer 106, may be provided in plurality. For example, as illustrated in FIG. 1, two second via holes H2 may be formed. However, the number of second via holes H2 is not limited thereto, and various numbers of second via holes H2 may be formed.

The second insulating layer 106 may include a second filler f2. A technical concept of the second filler f2 of the second insulating layer 106 is similar to the technical concept of the first filler f1 of the first insulating layer 103, and thus detailed descriptions of the second filler f2 are omitted.

A mixing proportion of the first filler f1 of the first insulating layer 103 may be different from the mixing proportion of the second filler f2 of the second insulating layer 106. For example, the second insulating layer 106 may have a relatively wider area of contact with the outside in comparison with the first insulating layer 103, and thus, the mixing proportion of the second filler f2 of the second insulating layer 106 may be higher than the mixing proportion of the first filler f1 of the first insulating layer 103. However, the mixing proportion of the first filler f1 of the first insulating layer 103 and the mixing proportion of the second filler f2 of the second insulating layer 106 are not limited thereto, and may be substantially the same.

A density of the first filler f1 in the first insulating layer 103 may vary. Furthermore, a density of the second filler f2 in the first insulating layer 103 may also vary. For example is, the first filler f1 may have a relatively high density in a region of the first insulating layer 103 adjacent to the first conductive via 104 and the redistribution pattern 105. Furthermore, the second filler f2 may have a relatively high density in a region of the second insulating layer 106 adjacent to the second conductive via 107 and the UBM 108. Therefore, a difference of heat transfer coefficient between the first conductive via 104 and the first insulating layer 103 and a difference of heat transfer coefficient between the redistribution pattern 105 and the first insulating layer 103 may be reduced. Furthermore, a difference of heat transfer coefficient between the second conductive via 107 and the second insulating layer 106 and a difference of heat transfer coefficient between the UBM 108 and the second insulating layer 106 may be reduced. Due to the reduction of the difference of heat transfer coefficient, the possibility of thermal damage to the semiconductor package 100 may be reduced.

The second via hole H2 may have a tapered shape. In more detail, the second via hole H2 may be tapered so that a cross-sectional area thereof increases in a direction away from the first insulating layer 103. However, the second via hole H2 is not limited thereto, and may have various shapes.

The second via hole H2 may be located on a further outer side than the first via hole H1. In other words, the second via hole H2 may be closer to a side surface of the semiconductor package 100 than the first via hole H1. Therefore, a separation distance d3 between the second via holes H2 may be greater than the separation distance d2 between the first via holes H1. However, the second via hole H2 is not limited thereto, and may be located on a further inner side than the first via hole H1.

A diameter of the second via hole H2 may be from about 5 micrometers to about 20 micrometers. For example, when the second via hole H2 has a tapered shape, the second via hole H2 may have a diameter of about 5 micrometers in a region adjacent to the first insulating layer 103 and may have a diameter of about 15 micrometers in a region adjacent to the UBM 108.

Furthermore, when the second via hole H2 has a cylindrical structure, the second via hole H2 may have the same diameter of about 10 micrometer in the region adjacent to the first insulating layer 103 and in the region adjacent to the UBM 108. However, the diameter of the second via hole H2 is not limited thereto, and may have various values according to various shapes of the second via hole H2.

The second conductive via 107 of the semiconductor package 100 according to an embodiment may be a conductive material filling the second via hole H2. The conductive material may be a metal material having excellent conductivity such as copper, gold, silver, or the like.

The second conductive via 107 may contact the redistribution pattern 105 and the UBM 108. Therefore, the various types of individual devices on the semiconductor chip 101 may be electrically connected to the external connection terminal 109 via the first conductive via 104, the redistribution pattern 105, the second conductive via 107, and the UBM 108.

The UBM 108 of the semiconductor package 100 according to an embodiment may be a pad for electrically connecting the redistribution pattern 105 to the external connection terminal 109. As illustrated in FIG. 1, the UBM 108 may be between the second conductive via 107 and the external connection terminal 109 and may electrically connect the redistribution pattern 105 to the external terminal 109.

As illustrated in FIG. 1, the UBM 108 may be buried in the second insulating layer 106. In more detail, a first surface 108i of the UBM 108 may be substantially flush with the second insulating layer 106. That is, a surface of the UBM 108 which faces the first surface 108i and side surfaces of the UBM 108 may be surrounded by the second insulating layer 106.

Unlike the illustration of FIG. 1, the first surface 108i of the UBM 108 may be closer to the semiconductor chip 101 than the first insulating layer 106. In other words, a surface formed due to a contact between the first surface 108i of the UBM 108 and the external connection terminal 109 may be closer to the semiconductor chip 101 than a surface of the second insulating layer 106, which is exposed to the outside. Therefore, a height difference may occur between the surface formed due to a contact between the first surface 108i of the UBM 108 and the external connection terminal 109 and the surface of the second insulating layer 106, which is exposed to the outside. As described above, the surface of the UBM 108, which faces the first surface 108i, and the side surfaces of the UBM 108 may be surrounded by the second insulating layer 106. Since the UBM 108 may be buried in the second insulating layer 106, the UBM 108 may be securely positioned in the second insulating layer 106 and the thickness of the semiconductor package 100 may decrease.

Referring to FIG. 1, the UBM 108 may be formed as a single metal layer. However, the UBM 108 is not limited thereto, and may be formed as a plurality of metal layers. A material of the UBM 108 may include a metal material having excellent conductivity such as copper, gold, silver, or the like. Furthermore, the material of the UBM 108 may be substantially the same as the material of the second conductive via 107. For example, when the material of the second conductive via 107 is copper, the material of the UBM 108 may include copper.

The external connection terminal 109 of the semiconductor package 100 according to an embodiment may be arranged under the UBM 108 and may be electrically connected to the UBM 108. Furthermore, the external connection terminal 109 may contact the first surface 108i of the UBM 108.

The semiconductor package 100 may be electrically connected by the external connection terminal 109 to an external device such as a system board or mainboard. The external connection terminal 109 may include a solder ball, as illustrated in FIG. 1. The solder ball may include at least one of tin, silver, copper, and aluminum. The solder ball may have a ball shape as illustrated in FIG. 1, but is not limited thereto, and may have various shapes such as a cylindrical shape, a polygonal column shape, a polyhedron shape, or the like.

The protective layer 110 of the semiconductor package 100 according to an embodiment may be arranged on the second surface 122 of the semiconductor chip 101. The protective layer 110 may be formed to protect the semiconductor chip 101 from a harmful environment. In an embodiment, the protective layer 110 may include an oxide film. The protective layer 110 may have a thickness of from about 15 micrometers to about 30 micrometers on the second surface 122 of the semiconductor chip 101.

In the semiconductor package 100 according to an embodiment, the redistribution pattern 105 and the UBM 108 may be buried in the first insulating layer 103 and the second insulating layer 106, respectively, and thus, a sum of the thicknesses of the first conductive via 104, the redistribution pattern 105, and the second conductive via 107 may be substantially the same as a sum of the thicknesses of the first insulating layer 103 and the second insulating layer 106. However, an embodiment is not limited thereto, and the sum of the thicknesses of the first conductive via 104, the redistribution pattern 105, and the second conductive via 107 may differ from the thicknesses of the first insulating layer 103 and the second insulating layer 106 within a range of from about 0.1 micrometers to about 10 micrometers.

In an example embodiment, the sum of the thicknesses of the first conductive via 104 and the redistribution pattern 105 may be substantially the same as the thickness of the first insulating layer 103. However, an embodiment is not limited thereto, and the sum of the thicknesses of the first conductive via 104 and the redistribution pattern 105 may differ from the thickness of the first insulating layer 103 within a range of from about 0.1 micrometers to about 10 micrometers.

Unlike the illustration of FIG. 1, the semiconductor package 100 according to an embodiment may include a plurality of redistribution patterns 105. Furthermore, the plurality of redistribution patterns 105 may be electrically connected to each other by a plurality of conductive vias.

The semiconductor package 100 according to embodiments may be manufactured using the semiconductor package manufacturing method including a stamping process to be described later. Accordingly, a manufacturing cost of the semiconductor package 100 may be reduced.

Furthermore, since the redistribution pattern 105 and the UBM 108 of the semiconductor package 100 according to embodiments may be buried in the first insulating layer 103 and the second insulating layer 106, respectively, the semiconductor package 100 may have excellent durability while having a small thickness and a light weight.

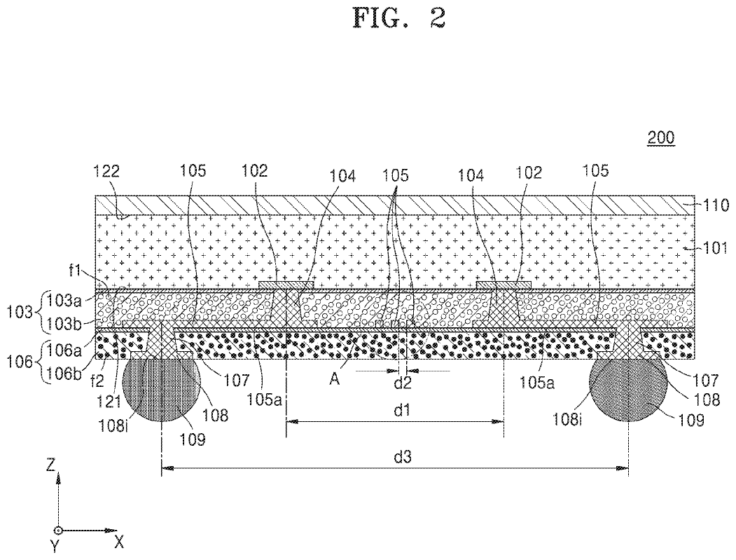

FIG. 2 is a cross-sectional view of a semiconductor package 200 according to an embodiment. Referring to FIG. 2, the semiconductor package 200 according to an embodiment may include the semiconductor chip 101, the chip pad 102, the first insulating layer 103, the first conductive via 104, the redistribution pattern 105, the second insulating layer 106, the second conductive via 107, the UBM 108, the external connection terminal 109, and the protective layer 110.

The first insulating layer 103 of the semiconductor package 200 of the present disclosure may include a first upper adhesive layer 103a and a first filler layer 103b. The first upper adhesive layer 103a may include an organic compound layer. For example, the first upper adhesive layer 103a may include a layer including epoxy. Furthermore, the first upper adhesive layer 103a may include a layer including an adhesive material and may include a layer not including the first filler f1.

The first upper adhesive layer 103a may be between the semiconductor chip 101 and the first filler layer 103b. The first filler layer 103b may include a layer including the first filler f1. The first filler layer 103b may be between the first upper adhesive layer 103a and the second insulating layer 106.

The second insulating layer 106 of the semiconductor package 200 of the present disclosure may include a second upper adhesive layer 106a and a second filler layer 106b. The second upper adhesive layer 106a may include an organic compound layer. For example, the second upper adhesive layer 106a may include a layer including epoxy. Furthermore, the second upper adhesive layer 106a may include a layer including an adhesive material and may include a layer not including the second filler f2.

The second upper adhesive layer 106a may be between the first filler layer 103b and the second filler layer 106b. The second filler layer 106b may include a layer including the second filler f2. The second filler layer 106b may be arranged on the second upper adhesive layer 106a, and a portion of the second filler layer 106b may be exposed to the outside.

Since the semiconductor package 200 of the present disclosure may include the first upper adhesive layer 103a, the first filler layer 103b may be securely attached on the semiconductor chip 101. Furthermore, since the semiconductor chip 200 may include the second upper adhesive layer 106a, the second filler layer 106b may be securely attached on the first insulating layer 103. Therefore, the semiconductor package 200 may be easily manufactured, and the possibility of damage to the semiconductor package 200 due to an external impact may be reduced.

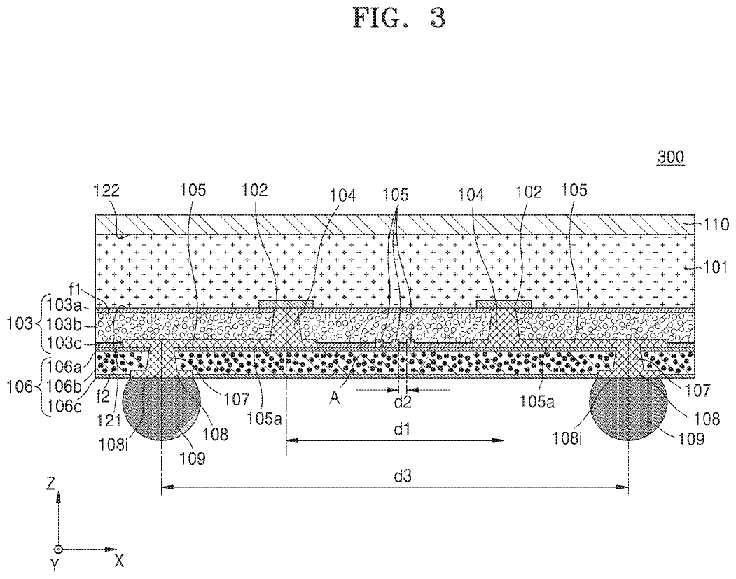

FIG. 3 is a cross-sectional view of a semiconductor package 300 according to an embodiment. Referring to FIG. 3, the semiconductor package 300 according to an embodiment may include the semiconductor chip 101, the chip pad 102, the first insulating layer 103, the first conductive via 104, the redistribution pattern 105, the second insulating layer 106, the second conductive via 107, the UBM 108, the external connection terminal 109, and the protective layer 110.

The first insulating layer 103 of the semiconductor package 300 of the present disclosure may include the first upper adhesive layer 103a, the first filler layer 103b, and a first lower adhesive layer 103c. Furthermore, the second insulating layer 106 may include the second upper adhesive layer 106a, the second filler layer 106b, and a second lower adhesive layer 106c. A technical concept of the first lower adhesive layer 103c and the second lower adhesive layer 106c may be substantially the same as the technical concept of the first upper adhesive layer 103a and the second upper adhesive layer 106a, and thus, detailed descriptions of the first lower adhesive layer 103c and the second lower adhesive layer 106c are omitted.

The first lower adhesive layer 103c of the first insulating layer 103 may be formed on the first filler layer 103b. The first filler layer 103b of the first insulating layer 103 may be between the first upper adhesive layer 103a and the first lower adhesive layer 103c. Since the first insulating layer 103 may include the first lower adhesive layer 103c on the first filler layer 103b, the first filler f1 may be prevented from escaping from the first filler layer 103b when forming the first via hole H1 and the redistribution pattern hole P1 by stamping the first insulating layer 103.

The second lower adhesive layer 106c of the second insulating layer 106 may be formed on the second filler layer 106b. The second filler layer 106b of the second insulating layer 106 may be between the second upper adhesive layer 106a and the second lower adhesive layer 106c. Since the second insulating layer 106 may include the second lower adhesive layer 106c on the second filler layer 106b, the second filler f2 may be prevented from escaping from the second filler layer 106b when forming the second via hole H2 and the UBM pattern hole P2 by stamping the second insulating layer 106.

Furthermore, since the semiconductor package 300 of the present disclosure may include the first lower adhesive layer 103c, the second insulating layer 106 may be securely formed on the first lower adhesive layer 103c. Accordingly, the possibility of damage to the semiconductor package 300 due to an external impact may be reduced.

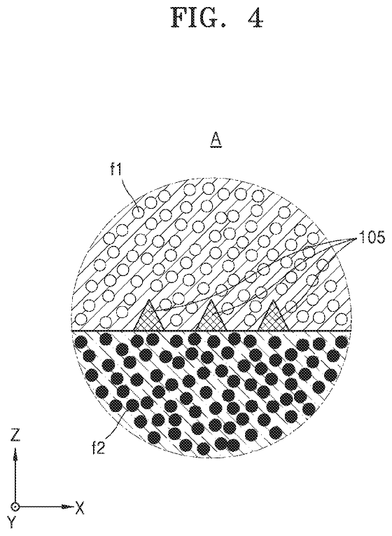

FIGS. 4 to 7 are cross-sectional views of the redistribution pattern 105 according to an embodiment. In more detail, FIGS. 4 to 7 are cross-sectional views of the redistribution pattern 105 in the region A illustrated in FIGS. 1 to 3. In an embodiment, the redistribution pattern 105 of the present disclosure may have a tapered shape having a cross-sectional area that decreases in a direction towards the semiconductor chip 101.

Referring to FIG. 4, the cross-section of the redistribution pattern 105 of the present disclosure may have a triangular shape. In more detail, the redistribution pattern 105 in the region A of FIG. 1 may have a cross-section shaped like an acute-angle triangle on an X-Z plane. For example, the redistribution pattern 105 in the region A may have a cross-section shaped like an isosceles triangle on the X-Z plane.

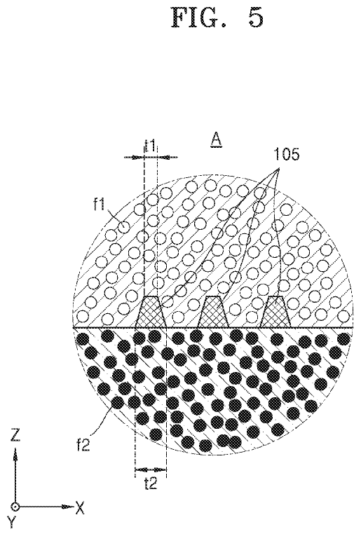

Referring to FIG. 5, the cross-section of the redistribution pattern 105 of the present disclosure may have a trapezoidal shape. In more detail, the redistribution pattern 105 in the region A of FIG. 1 may have a cross-section shaped like a trapezoid on the X-Z plane. For example, a length t1 of a first side of the redistribution pattern 105 which is parallel to the semiconductor chip 101 and relatively closer to the first insulating layer 103 may be less than a length t2 of a second side of the redistribution pattern 105 which is parallel to the semiconductor chip 101 and relatively closer to the second insulating layer 106.

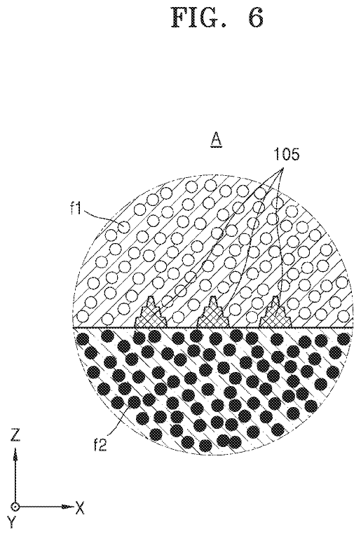

Referring to FIG. 6, the cross-section of the redistribution pattern 105 of the present disclosure may have a stair shape. In more detail, the redistribution pattern 105 in the region A of FIG. 1 may have a cross-section shaped like a stair having a width that decreases in a direction towards the semiconductor chip 101 on the X-Z plane.

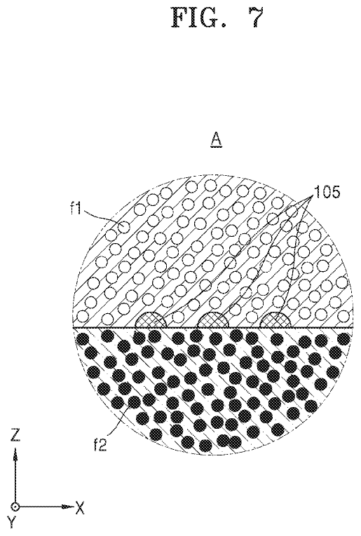

Referring to FIG. 7, the cross-section of the redistribution pattern 105 of the present disclosure may have a semicircular shape. In more detail, the redistribution pattern 105 in the region A of FIG. 1 may have a cross-section shaped like a semicircle having a width that decreases in a direction towards the semiconductor chip 101 on the X-Z plane.

The redistribution pattern 105 may be formed by filling, with a conductive material, the redistribution pattern hole P1 formed by a redistribution protrusion 43 (FIG. 11) of a stamp. The redistribution protrusion 43 may be tapered so that a cross-sectional area thereof decreases downwards. Therefore, the redistribution pattern hole P1 of the present disclosure may have a tapered shape having a cross-sectional area that decreases in a direction towards the semiconductor chip 101.

Since the redistribution protrusion 43 has a tapered shape as described above, detaching a stamp from the first insulating layer 103 after stamping the first insulating layer 103 may be easily performed. Furthermore, the upper surface of the first insulating layer 103 may be maintained as a planar surface.

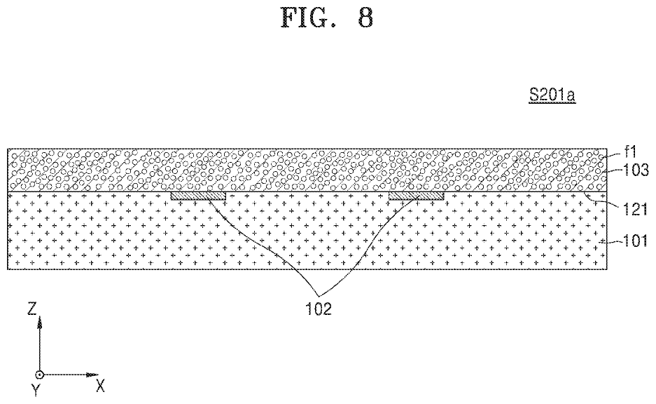

FIGS. 8 to 24 are diagrams illustrating a method of manufacturing a semiconductor package according to an embodiment.

The method of manufacturing a semiconductor package of the present disclosure may include forming the first insulating layer 103 on the first surface 121 of the semiconductor chip 101 (S201a, S201b), forming the first via hole H1 by stamping the first insulating layer 103 (S202), forming the redistribution pattern hole P1 by stamping the first insulating layer 103 (S203), etching the first via hole H1 (S204), forming the first conductive via 104 and the redistribution pattern 105 (S205), planarizing a first conductive material M1 (S206), forming the second insulating layer 106 on the first insulating layer 103 (S207a, S207b), forming the second via hole H2 and the UBM pattern hole P2 by stamping the second insulating layer 106 (S208), etching the second via hole H2 (S209), forming the second conductive via 107 and the UBM 108 (S210), planarizing the second conductive material M2 (S211), and mounting the external connection terminal 109 (S212).

FIG. 8 is a diagram illustrating forming the first insulating layer 103 on the first surface 121 of the semiconductor chip 101 (S201a) according to an embodiment. The method of manufacturing a semiconductor package of the present disclosure may include forming the first insulating layer 103 on the first surface 121 of the semiconductor chip 101 (S201a). In more detail, the forming of the first insulating layer 103 may include forming the first insulating layer 103 to a thickness of from about 10 micrometers to about 100 micrometers on the first surface 121 of the semiconductor chip 101 on which the chip pad 102 is formed. The first insulating layer 103 may include a non-photosensitive material as described above.

In an embodiment, the forming of the first insulating layer 103 (S201a) may include forming the first insulating layer 103 including the first filler f1 on the first surface 121 of the semiconductor chip 101. A technical concept of the first filler f1 is similar to the above technical concept described with reference to FIG. 1, and thus detailed descriptions of the first filler f1 are omitted here.

Since the first insulating layer 103 includes the first filler f1, the fluidity of the first insulating layer 103 may be adjusted. Since the fluidity of the first insulating layer 103 may be adjusted by the first filler f1, the first insulating layer 103 having a predetermined thickness or more may be formed on the first surface 121 of the semiconductor chip 101. For example, since the first insulating layer 103 may include the first filler f1, the first insulating layer 103 may be formed to a thickness of at least about 10 micrometers on the first surface 121 of the semiconductor chip 101.

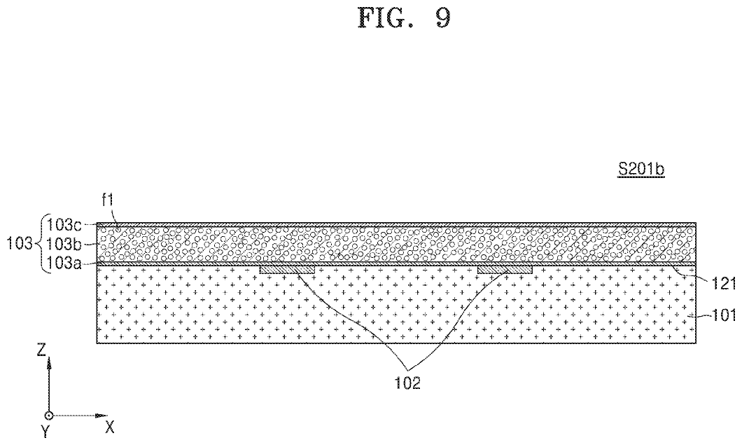

FIG. 9 is a diagram illustrating forming the first insulating layer 103 on the first surface 121 of the semiconductor chip 101 (S201b) according to an embodiment. The forming of the first insulating layer 103 (S201b) may include forming the first upper adhesive layer 103a on the first surface 121 of the semiconductor chip 101, forming the first filler layer 103b including the first filler f1 on the first upper adhesive layer 103a, and forming the first lower adhesive layer 103c on the first filler layer 103b.

In an embodiment, the forming of the first insulating layer 103 (S201) may include attaching, to the first surface 121 of the semiconductor chip 101, the film-type first insulating layer 103 in which the first upper adhesive layer 103a, the first filler layer 103b including the first filler f1, and the first lower adhesive layer 103c are sequentially stacked.

FIG. 10 is a diagram illustrating forming the first via hole H1 by stamping the first insulating layer 103 (S202) according to an embodiment. A method S200 of manufacturing a semiconductor package of the present disclosure may include forming the first via hole H1 by stamping the first insulating layer 103 (S202, hereinafter referred to as a first stamping process).

Referring to FIG. 10, the first stamping process S202 may include forming the first via hole H1 in the first insulating layer 103 by pressing, against the first insulating layer 103, the first stamp 41a including the first via hole protrusion 42 having a micrometer or nanometer size. The first via hole protrusion 42 of the first stamp 41a may form the first via hole H1 in the first insulating layer 103.

After the first stamping process S202, a curing process may be performed on the first insulating layer 103. The first via hole H1 may be stably formed in the first insulating layer 103 through the curing process. For example, the curing process may include a heat curing process, a light curing process, and the like.

As described above, since the first insulating layer 103 may include the first filler f1, forming the first via hole H1 by stamping the first insulating layer 103 may be easily performed. In more detail, since the fluidity of the first insulating layer 103 may be reduced due to the first filler f1 included therein, the flatness of a surface of the first insulating layer 103 may be maintained when detaching a stamp from the first insulating layer 103 after stamping the first insulating layer 103.

Furthermore, when the first stamp 411 has been detached, a shape of the first via hole H1 may substantially conform to a shape of the first via hole protrusion 42 of the first stamp 41a. In other words, since the first insulating layer 103 includes the first filler f1 and thus may be reduced in fluidity, the first via hole H1 may have a smoother shape than when the first insulating layer 103 does not include the first filler f1.

FIGS. 11 to 14 are diagrams illustrating forming the redistribution pattern hole P1 by stamping the first insulating layer 103 (S203) according to an embodiment. The method of manufacturing a semiconductor package of the present disclosure may include forming the redistribution pattern hole P1 by stamping the first insulating layer 103 (S203, hereinafter referred to as a second stamping process).

Referring to FIGS. 11 to 14, the second stamping process S203 may include forming the redistribution pattern hole P1 (FIG. 15) in the first insulating layer 103 by pressing, against the first insulating layer 103, the second stamp 41b including the redistribution protrusion 43 having a micrometer or nanometer size. The redistribution protrusion 43 of the second stamp 41b may form the redistribution pattern hole P1 in the first insulating layer 103.

The redistribution protrusion 43 may be tapered so that a cross-section thereof decreases downwards. Therefore, the redistribution pattern hole P1 formed by the redistribution protrusion 43 may also have a tapered shape having a cross-section that decreases in a direction towards the semiconductor chip 101. Since the redistribution protrusion 43 has a tapered shape, the second stamp 41b may be easily detached from the first insulating layer 103. Furthermore, when detaching the second stamp 41b from the first insulating layer 103, the flatness of a surface of the first insulating layer 103 may be maintained.

Referring to FIG. 11, the method of manufacturing a semiconductor package of the present disclosure may include forming the redistribution pattern hole P1 by stamping the first insulating layer 103 using the second stamp 41b including the redistribution protrusion 43 which has a triangular cross-section on the X-Z plane. Therefore, the redistribution pattern 105 of the semiconductor package 100 may have a triangular cross-section as described above.

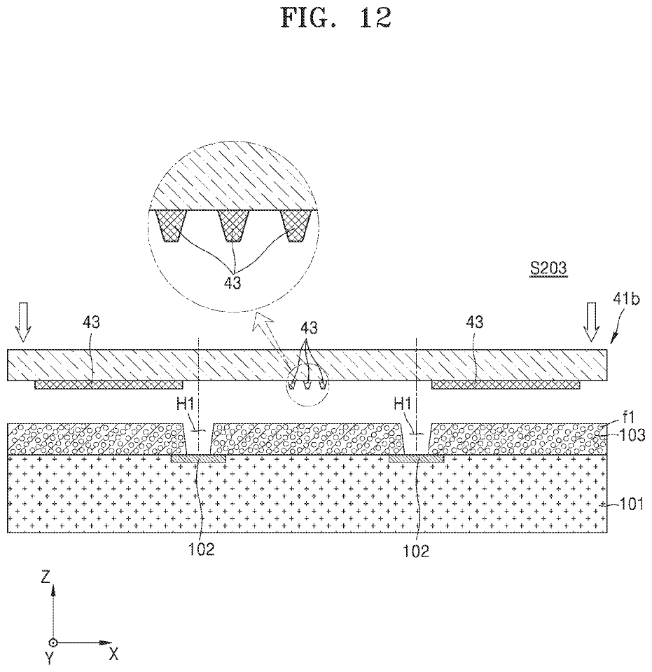

Referring to FIG. 12, the method of manufacturing a semiconductor package of the present disclosure may include forming the redistribution pattern hole P1 by stamping the first insulating layer 103 using the second stamp 41b including the redistribution protrusion 43 which has a trapezoidal cross-section on the X-Z plane. Therefore, the redistribution pattern 105 of the semiconductor package 100 may have a trapezoidal cross-section as described above.

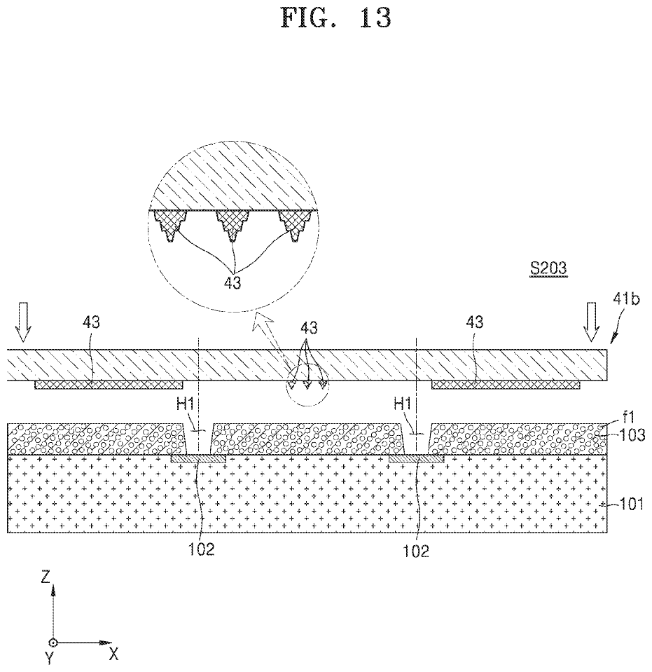

Referring to FIG. 13, the method of manufacturing a semiconductor package of the present disclosure may include forming the redistribution pattern hole P1 by stamping the first insulating layer 103 using the second stamp 41b including the redistribution protrusion 43 which has a stair-shaped cross-section on the X-Z plane. Therefore, the redistribution pattern 105 of the semiconductor package 100 may have a stair-shaped cross-section as described above.

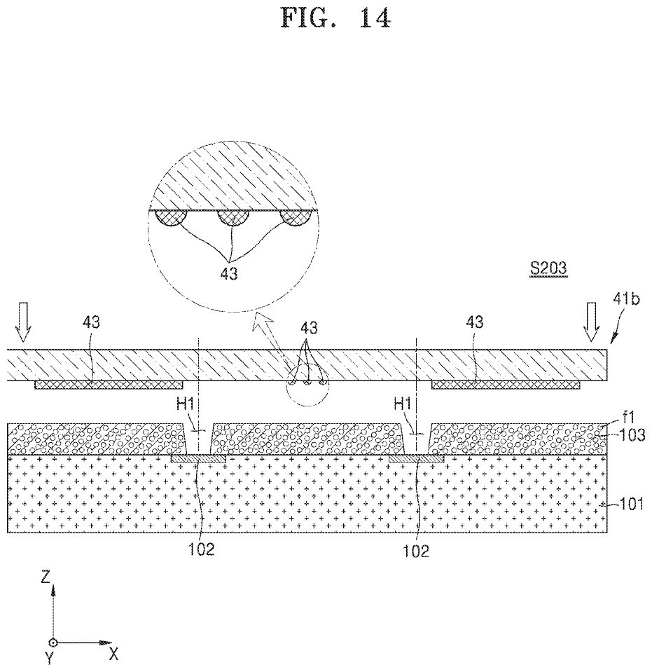

Referring to FIG. 14, the method of manufacturing a semiconductor package of the present disclosure may include forming the redistribution pattern hole P1 by stamping the first insulating layer 103 using the second stamp 41b including the redistribution protrusion 43 which has a semicircular cross-section on the X-Z plane. Therefore, the redistribution pattern 105 of the semiconductor package 100 may have a semicircular cross-section as described above.

A stamp according to an embodiment is not limited to the above descriptions, and may include both the first via hole protrusion 42 and the redistribution protrusion 43. Therefore, the method of manufacturing a semiconductor package of the present disclosure may include simultaneously forming the first via hole H1 and the redistribution pattern hole P1 by stamping the first insulating layer 103.

In the method S200 of manufacturing a semiconductor package according to an embodiment, the first insulating layer 103 may include various materials since the first via hole H1 and the redistribution pattern hole P1 may be formed through a stamping process. In more detail, the first insulating layer 103 may include a non-photosensitive material since the first via hole H1 and the redistribution pattern hole P1 may be formed in the first insulating layer 103 through a stamping process rather than a photolithography process. Therefore, a wider variety of materials may be chosen as the material of the first insulating layer 103, and the manufacturing cost of the semiconductor package 100 may be reduced.

FIG. 15 is a diagram illustrating etching the first via hole H1 (S204) according to an embodiment. The method of manufacturing a semiconductor package of the present disclosure may include etching the first via hole H1 (S204). In more detail, the etching of the first via hole H1 (S204) may include etching the first insulating layer 103 located on a lowermost portion of the first via hole H1. The etching of the first via hole H1 (S204) may include exposing the chip pad 102 by etching the first insulating layer 103 located on the lowermost portion of the first via hole H1.

The etching of the first via hole H1 (S204) may include etching the first via hole H1 through dry etching or wet etching.

In an example embodiment, the etching of the first via hole H1 (S204) may include etching the first via hole H1 using plasma. In more detail, the plasma etching process may include supplying electric energy to a process gas after injecting the process gas into a vacuum chamber. Due to the supplied electric energy, the process gas may become in a plasma state. Reactive atoms of the process gas dissociated in the plasma state may etch the first insulating layer 103 located on the lowermost portion of the first via hole H1, and may expose the chip pad 102 to the outside.

The etching of the first via hole H1 (S204) may optionally include cleaning the first via hole H1 through an ultrasonic cleaning process. The ultrasonic cleaning process may be performed after the plasma etching process.

The ultrasonic cleaning process may include exposing the chip pad 102 to the outside by removing the first insulating layer 103 on the first via hole H1 by applying high-frequency vibration energy to the first insulating layer 103 remaining on the lowermost portion of the first via hole H1 after the plasma etching process.

In cases when the chip pad 102 is sufficiently exposed since the first insulating layer 103 located on the lowermost portion of the first via hole H1 is etched through the plasma etching process, the above-mentioned ultrasonic cleaning process may be omitted during the etching of the first via hole H1 (S204) of the present disclosure.

In an embodiment, curing the first insulating layer 103 in which the first via hole H1 and the redistribution pattern hole P1 are formed may be performed. Through the curing process, the first via hole H1 and the redistribution pattern hole P1 may be stably formed in the first insulating layer 103.

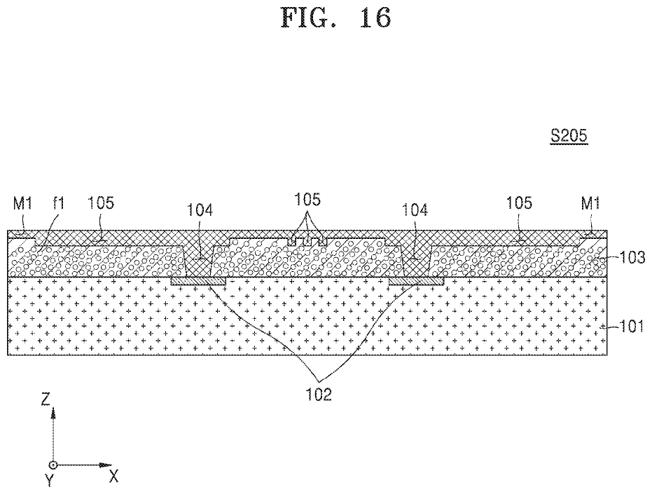

FIG. 16 is a diagram illustrating forming the first conductive via 104 and the redistribution pattern 105 (S205) according to an embodiment. The method of manufacturing a semiconductor package of the present disclosure may include forming the first conductive via 104 and the redistribution pattern 105 (S205). In more detail, the forming of the first conductive via 104 may include filling, with the first conductive material M1, the first via hole H1 formed through the above-mentioned stamping process and etching process. Furthermore, the forming of the redistribution pattern 105 may include filling, with the first conductive material M1, the redistribution pattern hole P1 formed through the above-mentioned stamping process. The first conductive material layer M1 may include various metal materials. For example, the first conductive material M1 may include a metal material having excellent conductivity such as copper, gold, silver, or the like.

When the forming of the first conductive via 104 and the redistribution pattern 105 (S205) is completed, the first conductive material M1 may cover the first insulating layer 103 at a thickness of from about 1 micrometer to about 4 micrometers.

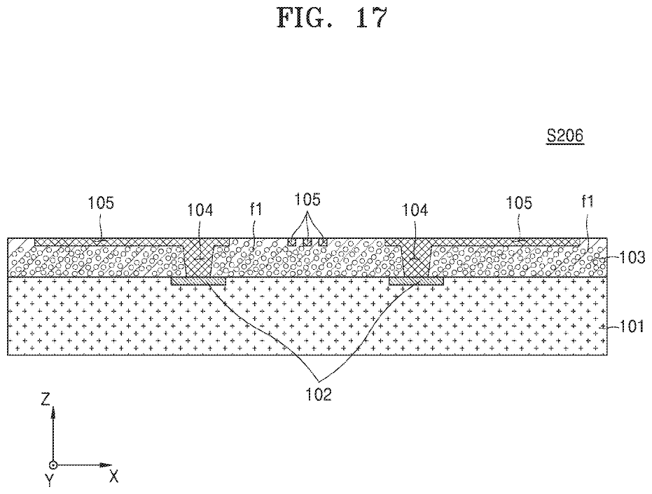

FIG. 17 is a diagram illustrating planarizing the first conductive material M1 (S206) according to an embodiment. The method of manufacturing a semiconductor package of the present disclosure may include planarizing the first conductive material M1 (S206). In more detail, the planarizing of the first conductive material M1 (S206) may include exposing the redistribution pattern 105 and the first insulating layer 103 to the outside by removing a portion of the first conductive material M1 which covers the first insulating layer 103 and the redistribution pattern 105 as described above. For example, the planarizing of the first conductive material M1 (S206) may include a chemical mechanical polishing (CMP) process and an etch-back process.

When the redistribution pattern 105 and the first insulating layer 103 are exposed to the outside, the first surface 105a of the redistribution pattern 105 and the first insulating layer 103 may be substantially flush with each other. Furthermore, a surface of the redistribution pattern 105, which faces the first surface 105a, and side surfaces thereof may be surrounded by the first insulating layer 103. Since the redistribution pattern 105 may be buried in the first insulating layer 103, the redistribution pattern 105 may be securely positioned in the first insulating layer 103 and the thickness of the semiconductor package 100 may decrease.

Unlike the illustration of FIG. 17, the first surface 105a of the redistribution pattern 105 may be closer to the semiconductor chip 101 than a surface of the first insulating layer 103 exposed to the outside. In other words, the first surface 105a of the redistribution pattern 105 may be closer to the semiconductor chip 101 than the surface of the first insulating layer 103 exposed to the outside. Therefore, a height difference may occur between the first surface 105a of the redistribution pattern 105 and the surface of the first insulating layer 103 exposed to the outside.

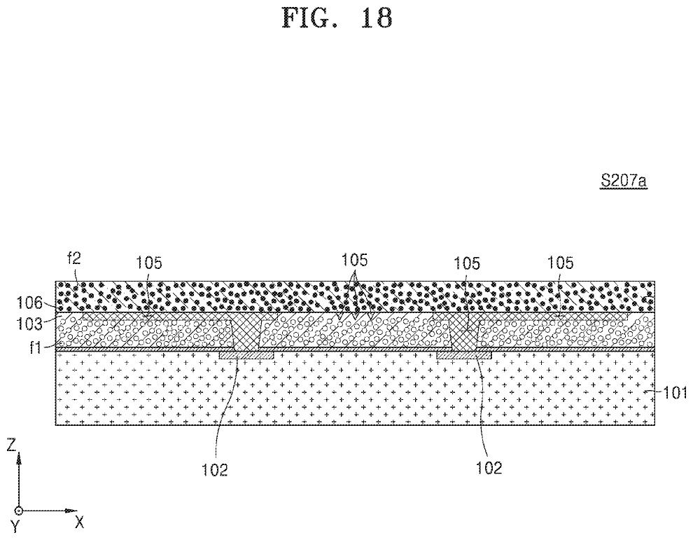

FIG. 18 is a diagram illustrating forming the second insulating layer 106 on the first insulating layer 103 (S207a) according to an embodiment. The method of manufacturing a semiconductor package of the present disclosure may include forming the second insulating layer 106 on the first insulating layer 103 (S207a). In more detail, the forming of the second insulating layer 106 (S207a) may include forming the second insulating layer 106 to a thickness of from about 10 micrometers to about 100 micrometers on the first insulating layer 103.

The first insulating layer 103 and the second insulating layer 106 may have substantially the same material. However, the materials of the first insulating layer 103 and the second insulating layer 106 are not limited thereto, and may be different.

The forming of the second insulating layer 106 (S207a) may include forming the second insulating layer 106 including the second filler f2 on the first insulating layer 103.

As described above, since the second insulating layer 106 includes the second filler f2, the fluidity of the second insulating layer 106 may be adjusted. Since the fluidity of the second insulating layer 106 may be adjusted by the second filler f2, the second insulating layer 106 having a predetermined thickness or more may be formed on the first insulating layer 103. For example, since the second insulating layer 106 may include the second filler f2, the second insulating layer 106 may be formed to a thickness of at least about 10 micrometers on the first insulating layer 103.

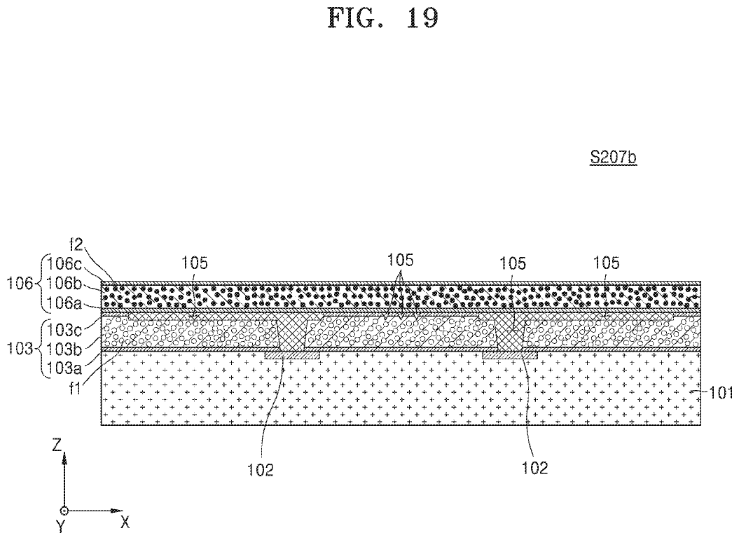

FIG. 19 is a diagram illustrating forming the second insulating layer 106 on the first insulating layer 103 (S207b) according to an embodiment. The forming of the second insulating layer 106 (S207b) may include forming the second upper adhesive layer 106a on the first insulating layer 103, forming the second filler layer 106b including the second filler f2 on the second upper adhesive layer 106a, and forming the second lower adhesive layer 106c on the second filler layer 106b.

In an embodiment, the forming of the second insulating layer 106 (S207b) may include attaching, to the first insulating layer 103, the film-type second insulating layer 106 in which the second upper adhesive layer 106a, the second filler layer 106b including the second filler f2, and the second lower adhesive layer 106c are sequentially stacked.

Since the second insulating layer 106 may include the second lower adhesive layer 106c, the second filler f2 may be prevented from escaping from the second filler layer 106b when forming the second via hole H2 and the UBM pattern hole P2.

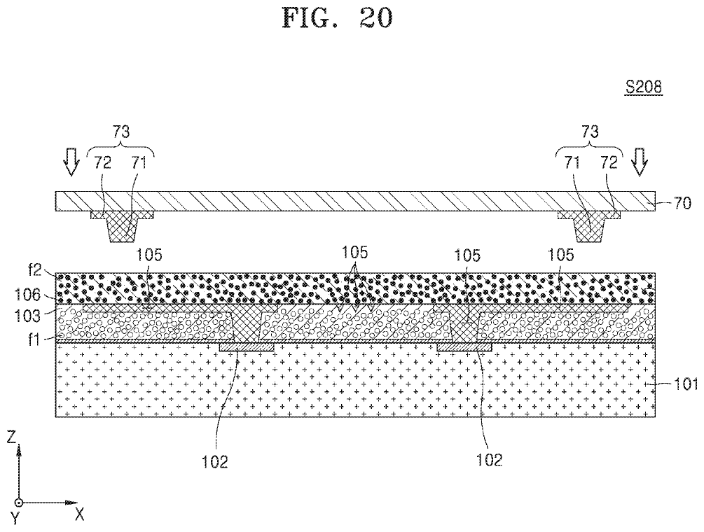

FIG. 20 is a diagram illustrating forming the second via hole H2 and the UBM pattern hole P2 by stamping the second insulating layer 106 (S208, hereinafter referred to as a third stamping process) according to an embodiment. The method of manufacturing a semiconductor package of the present disclosure may include forming the second via hole H2 and the UBM pattern hole P2 by stamping the second insulating layer 106. A technical concept of the third stamping process is substantially the same as the above-mentioned technical concept of the first and second stamping processes, and is thus not described in detail.

The third stamping process S208 may include forming the second via hole H2 and the UBM pattern hole P2 in the second insulating layer 106 by pressing, against the second insulating layer 106, a third stamp 70 including a protrusion 73 having a micrometer or nanometer size. For example, the third stamping process S208 may include simultaneously forming the second via hole H2 and the UBM pattern hole P2 in the second insulating layer 106.

The protrusion 73 of the third stamp 70 may include a second via hole protrusion 71 and a UBM protrusion 72. In more detail, the second via hole protrusion 71 may form the second via hole H2 in the second insulating layer 106, and the UBM protrusion 72 may form the UBM pattern hole P2 in the second insulating layer 106.

A curing process may be further performed after the third stamping process S208. The second via hole H2 and the UBM pattern hole P2 may be stably formed in the second insulating layer 106 through the curing process.

In the method of manufacturing a semiconductor package according to an embodiment, the second insulating layer 106 may include various materials since the second via hole H2 and the UBM pattern hole P2 may be formed through the third stamping process S208. In more detail, the second insulating layer 106 may include not only a photosensitive material but also a non-photosensitive material since the second via hole H2 and the UBM pattern hole P2 may be formed in the second insulating layer 106 through the third stamping process S208 rather than a photolithography process. Therefore, a wider variety of materials may be chosen as the material of the second insulating layer 106, and the manufacturing cost of the semiconductor package 100 may be reduced.

Since the second insulating layer 106 may include the second filler f2, the forming of the second via hole H2 and the UBM pattern hole P2 by stamping the second insulating layer 106 (S208) may be easily performed. In more detail, since the fluidity of the second insulating layer 106 may be reduced due to the second filler f2 included therein, a surface of the second insulating layer 106 may be planar when detaching the third stamp 70 from the second insulating layer 106 after stamping the second insulating layer 106 using the third stamp 70. Furthermore, when the third stamp 70 has been detached, shapes of the second via hole H2 and the UBM pattern hole P2 formed on the second insulating layer 106 may substantially conform to shapes of the second via hole protrusion 71 and the UBM protrusion 72 of the third stamp 70 respectively. In other words, since the second insulating layer 106 includes the second filler f2 and thus may be reduced in fluidity, the second via hole H2 and the UBM pattern hole P2 may have smoother shapes than when the second insulating layer 106 does not include the second filler f2.

FIG. 21 is a diagram illustrating etching the second via hole H2 (S209) according to an embodiment. The method of manufacturing a semiconductor package of the present disclosure may include etching the second via hole H2 (S209). In more detail, the etching of the second via hole H2 (S209) may include etching the second insulating layer 106 located on a lowermost portion of the second via hole H2. The redistribution pattern 105 may be exposed by etching the second insulating layer 106 located on the lowermost portion of the second via hole H2.

The etching of the second via hole H2 (S209) may include etching the second via hole H2 through dry etching or wet etching. In an example, the etching of the second via hole H2 may include etching the second via hole H2 through the above-mentioned plasma etching process. Furthermore, the etching of the second via hole H2 (S209) may optionally include the above-mentioned ultrasonic cleaning process. A technical concept of these plasma etching process and ultrasonic cleaning process is the same as the above-mentioned technical concept, and is thus not described in detail.

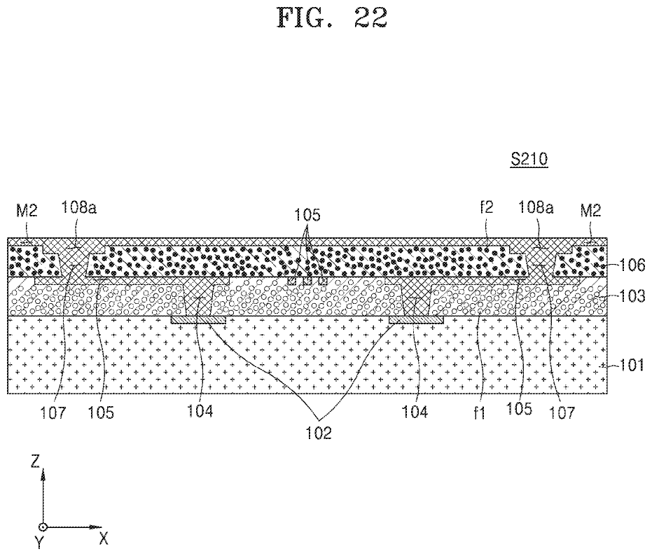

FIG. 22 is a diagram illustrating forming the second conductive via 107 and the UBM 108 according to an embodiment. The method of manufacturing a semiconductor package of the present disclosure may include forming the second conductive via 107 and the UBM 108 (S210). In more detail, the forming of the second conductive via 107 may include filling, with the second conductive material M2, the second via hole H2 formed through the above-mentioned third stamping process S208 and etching process S209. Furthermore, the forming of the UBM 108 may include filling, with the second conductive material M2, the UBM pattern hole P2 formed through the above-mentioned third stamping process S208. This conductive material may include various metal materials. For example, the second conductive material M2 may include a metal material having excellent conductivity such as copper, gold, silver, or the like.

When the forming of the second conductive via 107 and the UBM 108 (S210) is completed, the second conductive material M2 may cover the second insulating layer 106 and the UBM 108 at a thickness of from about 1 micrometer to about 4 micrometers.

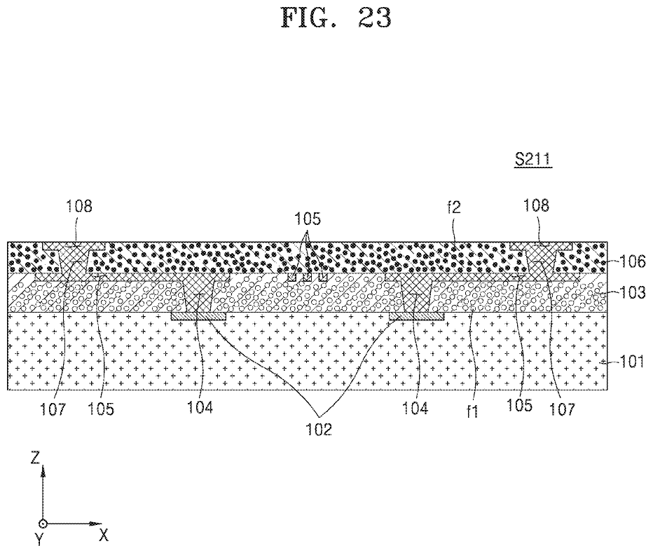

FIG. 23 is a diagram illustrating planarizing the second conductive material M2 (S211) according to an embodiment. The method of manufacturing a semiconductor package of the present disclosure may include planarizing the second conductive material M2 (S211). In more detail, the planarizing of the second conductive material M2 (S211) may include exposing the UBM 108 and the second insulating layer 106 to the outside by removing a portion of the second conductive material M2 which covers the second insulating layer 106 and the UBM 108 as described above.

When the second insulating layer 106 and the UBM 108 are exposed to the outside, the second insulating layer 106 and the first surface 108i of the UBM 108 may be substantially flush with each other. Furthermore, a surface of the UBM 108, which faces the first surface 108i, and side surfaces thereof may be surrounded by the second insulating layer 106. Since the UBM 108 may be buried in the second insulating layer 106, the UBM 108 may be securely positioned in the second insulating layer 106 and the thickness of the semiconductor package 100 may decrease.

Unlike the illustration of FIG. 23, a surface of the UBM 108 exposed to the outside may be closer to the semiconductor chip 101 than a surface of the second insulating layer 106 exposed to the outside. Therefore, a height difference may occur between the surface of the UBM 108 exposed to the outside and the surface of the second insulating layer 106 exposed to the outside.

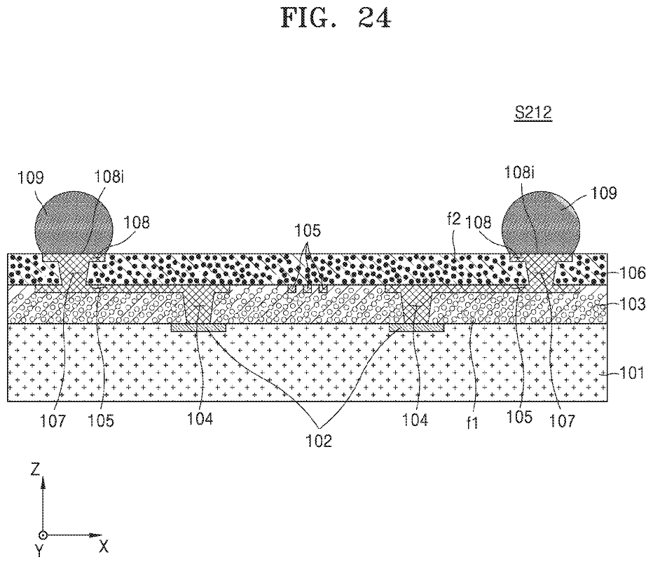

FIG. 24 is a diagram illustrating mounting the external connection terminal 109 according to an embodiment. The method of manufacturing a semiconductor package of the present disclosure may include mounting the external connection terminal 109 (S212). In more detail, the mounting of the external connection terminal 109 (S212) may include electrically connecting the UBM 108 and the external connection terminal 109 by mounting the external connection terminal 109 on the UBM 108.

Referring to FIG. 24, the mounting of the external connection terminal 109 may include mounting the external connection terminal 109 so that the external connection terminal 109 is in contact with the first surface 108i of the UBM 108. Furthermore, the mounting of the external connection terminal 109 (S212) may include processing the external connection terminal 109 into various shapes such as a cylindrical shape, a polygonal column shape, a polyhedron shape, or the like.

The method of manufacturing a semiconductor package according to embodiments may reduce the manufacturing cost of a semiconductor package through the above-mentioned processes included in the method.

Furthermore, the method of manufacturing a semiconductor package according to embodiments may make it possible to manufacture a thin and light semiconductor package having excellent durability through the above-mentioned processes included in the method.

Example embodiments have been described with reference to the drawings. Although specific terms are used herein to describe embodiments, the terms are only used to describe the technical concept of the present disclosure, and are not intended to limit the meanings or limit the scope of the present disclosure set forth in the claims. Therefore, those of ordinary skill in the art could understand that various modifications and other equivalent embodiments can be made from the present disclosure. Therefore, the technical protection scope of the present disclosure should be determined by the technical concept of the following claims.

What is claimed is:

1. A semiconductor package comprising:
a semiconductor chip having a first surface in which a chip pad is formed;
a first insulating layer arranged on the first surface of the semiconductor chip and comprising a first filler;
a first conductive via electrically connected to the chip pad and formed to penetrate the first insulating layer; and
a redistribution pattern electrically connected to the first conductive via and buried in the first insulating layer.

2. The semiconductor package of claim 1, further comprising:
a second insulating layer contacting the redistribution pattern on the first insulating layer and comprising a second filler;
a second conductive via electrically connected to the redistribution pattern and formed to penetrate the second insulating layer;
an under bump material (UBM) electrically connected to the second conductive via and buried in the second insulating layer; and
an external connection terminal electrically connected to the UBM.

3. The semiconductor package of claim 2, wherein the first filler and the second filler comprise at least one of silica and alumina, and have a size of from about 0.1 micrometers to about 10 micrometers.

4. The semiconductor package of claim 2, wherein the first conductive via has a tapered shape, and has a diameter of from 5 micrometers to 20 micrometers.

5. The semiconductor package of claim 2, wherein the first insulating layer has a thickness of from 10 micrometers to 100 micrometers,
wherein the second insulating layer has a thickness of from 10 micrometers to 100 micrometers.

6. The semiconductor package of claim 2, wherein the redistribution pattern has a thickness of from 1 micrometer to 5 micrometers.

7. The semiconductor package of claim 2, wherein a mixing proportion of the first filler of the first insulating layer is different from a mixing proportion of the second filler of the second insulating layer.

8. The semiconductor package of claim 7, wherein the mixing proportion of the first filler of the first insulating layer is lower than the mixing proportion of the second filler of the second insulating layer.

9. The semiconductor package of claim 2, wherein the first insulating layer comprises:
a first upper adhesive layer on the semiconductor chip; and
a first filler layer arranged on the first upper adhesive layer and comprising the first filler, and
wherein the second insulating layer comprises:
a second upper adhesive layer on the first filler layer; and
a second filler layer arranged on the second upper adhesive layer and comprising the second filler.

10. The semiconductor package of claim 9, wherein the first insulating layer further comprises a first lower adhesive layer between the first filler layer and the second upper adhesive layer, and
wherein the second insulating layer further comprises a second lower adhesive layer on the second filler layer.

11. The semiconductor package of claim 1, wherein the first filler has a high density in a region of the first insulating layer adjacent to the first conductive via and the redistribution pattern.

12. The semiconductor package of claim 1, wherein the redistribution pattern is tapered so that a cross-sectional area thereof decreases in a direction towards the semiconductor chip.

13. The semiconductor package of claim 1, wherein a sum of thicknesses of the first conductive via and the redistribution pattern is the same as a thickness of the first insulating layer.

14. The semiconductor package of claim 1, wherein a lower surface of the redistribution pattern is closer to the semiconductor chip in a vertical direction than an upper surface of the first insulating layer.

15. A semiconductor package comprising:
a semiconductor chip having a first surface in which a chip pad is formed;
a first insulating layer on the first surface of the semiconductor chip;
a first conductive via electrically connected to the chip pad and formed to penetrate the first insulating layer;
a redistribution pattern electrically connected to the first conductive via and buried in the first insulating layer;
a second insulating layer contacting the redistribution pattern on the first insulating layer;
a second conductive via electrically connected to the redistribution pattern and formed to penetrate the second insulating layer;
an under bump material (UBM) electrically connected to the second conductive via and buried in the second insulating layer; and
an external connection terminal electrically connected to the UBM,
wherein the redistribution pattern
is tapered so that a cross-sectional area thereof decreases in a direction towards the semiconductor chip.

16. The semiconductor package of claim 15, wherein a cross-section of the redistribution pattern has a shape of at least one of a triangle, a trapezoid, a stair, and a semicircle.

17. The semiconductor package of claim 15, wherein the first insulating layer comprises a first filler, and the second insulating layer comprises a second filler.

18. A method of manufacturing a semiconductor package, the method comprising:
forming a first insulating layer on a first surface of a semiconductor chip in which a chip pad is formed, the first insulating layer comprising a first filler;
forming a first via hole and a redistribution pattern hole by stamping the first insulating layer;
forming a first conductive via and a redistribution pattern by filling the first via hole and the redistribution pattern hole with a first conductive material;
forming a second insulating layer on the first insulating layer, the second insulating layer comprising a second filler;
forming a second via hole and an under bump material (UBM) pattern hole by stamping the second insulating layer; and
forming a second conductive via and a UBM by filling the second via hole and the UBM pattern hole with a second conductive material.

19. The method of claim 18, wherein the forming of the first insulating layer comprises:
forming a first upper adhesive layer on the first surface of the semiconductor chip;
forming a first filler layer on the first upper adhesive layer, the first filler layer comprising the first filler; and
forming a first lower adhesive layer on the first filler layer
wherein the forming of the second insulating layer comprises:
forming a second upper adhesive layer on the first insulating layer;
forming a second filler layer on the second upper adhesive layer, the second filler layer comprising the second filler; and
forming a second lower adhesive layer on the second filler layer.

20. The method of claim 18, wherein the forming of the redistribution pattern hole comprises stamping the first insulating layer to form the redistribution pattern hole having a tapered shape, a cross-sectional area of which decreases in a direction towards the first surface of the semiconductor chip, and
wherein the tapered shape comprises at least one of a triangle, a trapezoid, a stair, and a semicircle.
